(19) United States
(12) Patent Application Publication
(10) Pub. No.: US 2015/0349805 A1
(43) Pub. Date: Dec. 3, 2015

(54) Method of Handling Error Correcting Code in Non-volatile Memory and Non-volatile Storage Device Using the Same

(71) Applicant: Skymedi Corporation, Hsinchu (TW)

(72) Inventors: Tzung-Shiang Tsai, Hsinchu (TW); Chia-Chen Chang, Hsinchu (TW)

(73) Assignee: Skymedi Corporation, Hsinchu (TW)

(21) Appl. No.: 14/289,627

(22) Filed: May 28, 2014

(51) Int. Cl. H03M 13/29; H03M 13/00

(52) U.S. Cl. CPC H03M 13/2906; H03M 13/6312

(57) ABSTRACT

A method of handling an error correcting code (ECC) in a non-volatile memory includes performing a first ECC operation on data codes to generate first parity codes; compressing the first parity codes to generate compressed parity codes; performing a second ECC operation on the compressed parity codes to generate additional parity codes; and writing the data codes, the compressed parity codes and the additional parity codes into a memory unit of the non-volatile memory.

### BACKGROUND OF THE INVENTION

1. Field of the Invention

The present invention relates to a method of handling error correcting codes (ECC) in a non-volatile memory and a non-volatile storage device using the same, and more particularly, to a method of handling ECC in a non-volatile memory capable of improving the life of the non-volatile memory and a non-volatile storage device using the same.

2. Description of the Prior Art

A memory controller is commonly utilized for task management in a memory system, especially in a non-volatile memory system. In general, since data stored in a non-volatile memory system may not be lost after electric power of the non-volatile memory system is cut off, the non-volatile memory system becomes an important means to store system data. Among those non-volatile memory systems, NAND flash memory, which has advantages of low power and high speed, becomes popular with the popularization of portable devices in recent years.

However, there is a limitation on the life of the NAND flash memory since the NAND flash memory has a finite number of program/erase cycles. In order to improve the life of the NAND flash memory, two main approaches may be applied. One approach manages the small size mapping in a flash translation layer (FTL) to reduce the write amplification. The other uses error correcting code (ECC) techniques to correct more error bits in data stored in the flash memory. With the increasing times of program/erase operations performed on the NAND flash memory, bit corruptions will become severe and an ECC policy with a higher error correction capability is therefore required. In such a condition, more parity codes are required for performing error corrections, while there is a finite space for storing these parity codes in the NAND flash memory. Thus, there is a need to efficiently allocate parity codes and enhance the error correction capability of the NAND flash memory by adaptively applying ECC policies.

### SUMMARY OF THE INVENTION

It is therefore an objective of the present invention to provide a method of handling an error correcting code (ECC) in a non-volatile memory, which is capable of improving the life of the non-volatile memory by adaptively applying ECC policies to efficiently store the parity codes in the limited storage space of the non-volatile memory.

The present invention discloses a method of handling an ECC in a non-volatile memory. The method comprises performing a first ECC operation on data codes to generate first parity codes; compressing the first parity codes to generate compressed parity codes; performing a second ECC operation on the compressed parity codes to generate additional parity codes; and writing the data codes, the compressed parity codes and the additional parity codes into a memory unit of the non-volatile memory.

The present invention further discloses a non-volatile storage device. The non-volatile storage device comprises a non-volatile memory; and a memory controller, coupled to the non-volatile memory, for handling an ECC in the non-volatile memory. The memory controller comprises a memory buffer; an ECC module, for performing a first ECC operation on data codes stored in the memory buffer to generate first parity codes; a compression module, for compressing the first parity codes to generate compressed parity codes, wherein the ECC module further performs a second ECC operation on the compressed parity codes to generate additional parity codes; and a processor, for writing the data codes, the compressed parity codes and the additional parity codes into a memory unit of the non-volatile memory.

The present invention further discloses a method of handling an ECC in a non-volatile memory. The method comprises dividing a memory unit of the non-volatile memory into a data region and a spare region; dividing first data codes into N code words; performing a first ECC operation on the N code words to generate N sets of first parity codes; and allocating N parts of the data region to store the N code words and N parts of the spare region to store the N sets of the first parity codes, respectively; wherein a size of each of the N parts of the spare region is not smaller than a value determined according to a size of second parity codes generated by performing a second ECC operation on any one of the N code words.

The present invention further discloses a non-volatile storage device. The non-volatile storage space comprises a non-volatile memory, comprising a memory unit divided into a data region and a spare region; and a memory controller, coupled to the non-volatile memory, for handling an ECC in the non-volatile memory by executing the following steps: dividing first data codes into N code words; performing a first ECC operation on the N code words to generate N sets of first parity codes; and allocating N parts of the data region to store the N code words and N parts of the spare region to store the N sets of the first parity codes, respectively; wherein a size of each of the N parts of the spare region is not smaller than a value determined according to a size of second parity codes generated by performing a second ECC operation on any one of the N code words.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a non-volatile storage device according to an embodiment of the present invention.

FIG. 2 is an error correction process according to an embodiment of the present invention.

FIG. 3A is a flow chart of data codes and parity codes to be written into a memory unit of the non-volatile memory according to an embodiment of the present invention.

FIG. 3B is a flow chart of data codes and parity codes to be written into a memory unit of the non-volatile memory according to another embodiment of the present invention.

FIG. 4 is an error correction process according to another embodiment of the present invention.

FIG. 5 is a flowchart of storage space in a memory unit reserved for parity codes based on an ECC operation with a higher error correction capability according to an embodiment of the present invention.

FIG. 6 is a schematic diagram of a comparison between the memory unit in the above embodiment and a general memory unit when a lower level ECC operation is applied.

FIG. 7 is a schematic diagram of a placement of a data region and a spare region in a memory unit according to an embodiment of the present invention.

### DETAILED DESCRIPTION

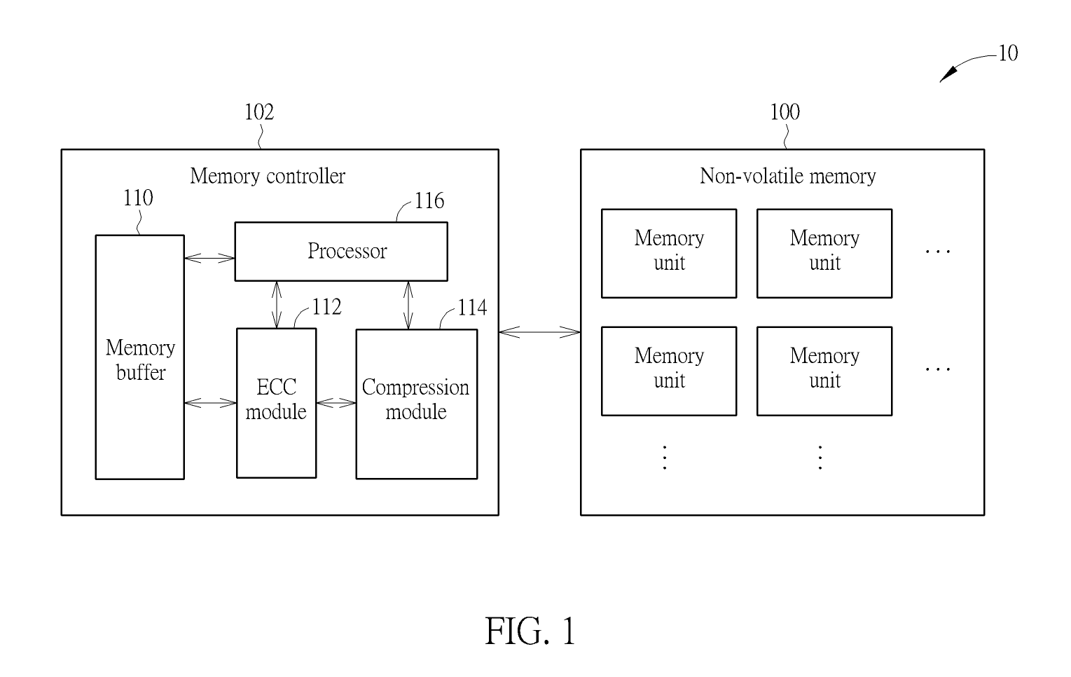

Please refer to FIG. 1, which is a schematic diagram of a non-volatile storage device 10 according to an embodiment of the present invention. As shown in FIG. 1, the non-volatile storage device 10 includes a non-volatile memory 100 and a memory controller 102. The non-volatile memory 100 includes a plurality of memory units, wherein each memory unit may be a page or a partial program page (e.g. 1 kB or 2 kB) according to the mapping unit defined by the memory controller 102 and the characteristic of the non-volatile memory 100. The partial program page is apart of a page, wherein a page may include a plurality of partial program pages. The memory controller 102, coupled to the non-volatile memory 100, is utilized for writing data in the non-volatile memory 100 and managing the non-volatile memory 100. The memory controller 102 includes a memory buffer 110, an ECC module 112, a compression module 114 and a processor 116. A flash translation layer (FTL) is included in the memory controller 102 for managing the mapping relationship corresponding to each memory unit of the non-volatile memory 100. The memory controller 102 may also manage the strategy for writing data in each memory unit, e.g. various types of error correcting code (ECC) or different programming methods. The non-volatile storage device 10 may be coupled to a host interface to communicate with a host or store data of the host according to user requirements. The host interface may be an embedded multimedia card (eMMC), a secure digital (SD) memory card, a universal serial bus (USB) interface, a peripheral component interconnect express (PCIe) interface or a serial advanced technology attachment (SATA) interface, etc., which is utilized for connecting a host such as a tablet, a computer, a mobile phone and a vehicle device.

In detail, the memory buffer 110 is utilized for temporarily storing the data which will be written into the non-volatile memory 100 later or may be read from the non-volatile memory 100. The ECC module 112 is utilized for performing ECC operations on data codes to be stored in the non-volatile memory 100 and generating corresponding parity codes for error corrections in the data codes. In an embodiment, the ECC module 112 may include a plurality of ECC circuits, each of which may realize an ECC engine and perform a specific ECC operation on the data codes. In another embodiment, the ECC module 112 may include an ECC circuit capable of realizing various ECC engines and performing various ECC operations on the data codes, wherein the processor 116 is capable of selecting an ECC operation to be performed on the data codes among the available ECC operations. Such ECC engines may be of any types such as BCH codes or low-density parity-check (LDPC) codes. The compression module 114 is utilized for performing compression or decompression operations on the parity codes. The compression operations allow the parity codes to have a smaller size to be stored. The processor 116 may manage the operations of the memory controller 102. Such operations may include read/write operations and the abovementioned ECC operations and compression/decompression operations, and may also include other fundamental operations specified in the FTL. In some embodiments of the present invention, the processor 116 may be utilized for selecting which ECC policy to be applied.

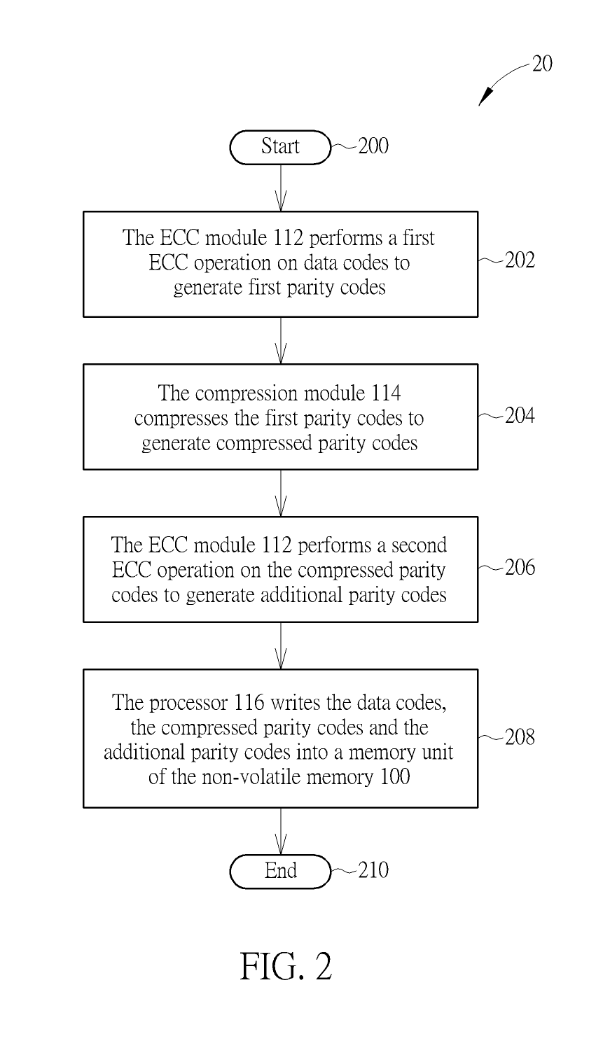

Please refer to FIG. 2, which is an error correction process 20 according to an embodiment of the present invention. As shown in FIG. 2, the error correction process 20, which may be realized by the memory controller 102 of the non-volatile storage device 10, includes the following steps:

Step 200: Start.

Step 202: The ECC module 112 performs a first ECC operation on data codes to generate first parity codes.

Step 204: The compression module 114 compresses the first parity codes to generate compressed parity codes.

Step 206: The ECC module 112 performs a second ECC operation on the compressed parity codes to generate additional parity codes.

Step 208: The processor 116 writes the data codes, the compressed parity codes and the additional parity codes into a memory unit of the non-volatile memory 100.

Step 210: End.

According to the error correction process 20, before the data codes are programmed into the memory unit of the non-volatile memory 100, they first undergo a first ECC operation performed by the ECC module 112 to generate the first parity codes. The compression module 114 then compresses the first parity codes to generate the compressed parity codes. The ECC module 112 further performs a second ECC operation on the compressed parity codes to generate the additional parity codes. Finally, the data codes, the compressed parity codes and the additional parity codes are programmed into the memory unit in a write operation performed by the processor 116, wherein the memory unit may be a memory page having a unit of size on which a programming operation is performed or a partial program page. Please note that, the first ECC operation and the second ECC operation may be of the same type but with different error correction capabilities, or of different types. Both the first ECC operation and the second ECC operation may be any type of ECC engine realized by the ECC module 112.

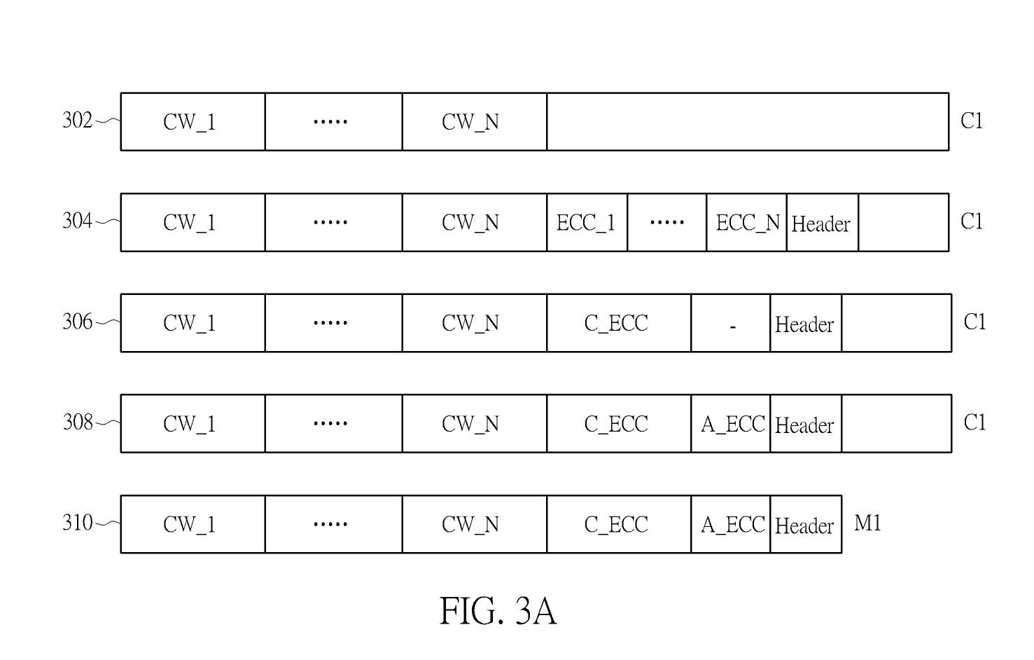

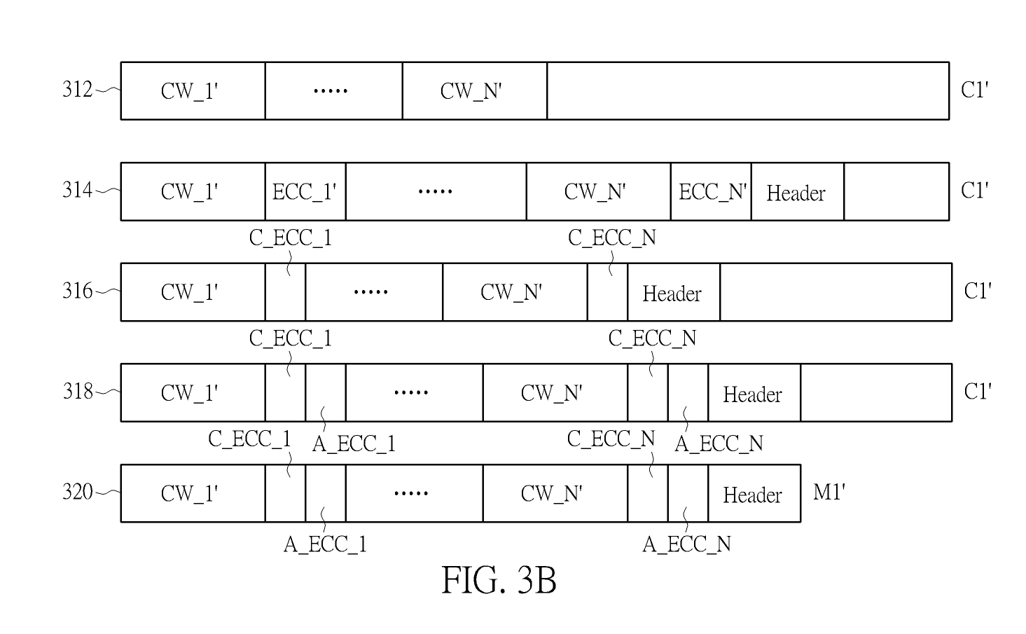

Please refer to FIG. 3A, which is a flow chart of data codes and parity codes to be written into a memory unit M1 of the non-volatile memory 100 according to an embodiment of the present invention. As shown in FIG. 3A, the data codes and the parity codes to be written into the memory unit M1 are first stored in a cache memory C1, wherein the cache memory C1 may be any one or a combination of a storage space included in the memory buffer 110, other memory buffer of the ECC module 112 and other static random access memory (SRAM) allocated for the memory controller 102. The data codes may be divided into code words CW_1-CW_N (Step 302). After the first ECC operation, parity codes ECC_1-ECC_N corresponding to the code words CW_1-CW_N are generated and stored in the cache memory C1 following the code words CW_1-CW_N (Step 304). A header recording the logical address, the ECC policy information (e.g. the applied ECC type, correction capability of the applied ECC policy and protection methods of the applied ECC policy) and other management information related to the data codes is also stored in the cache memory C1. The compression module 114 then compresses the parity codes ECC_1-ECC_N to generate compressed parity codes C_ECC, which replace the parity codes ECC_1-ECC_N to be stored in the cache memory C1 (Step 306). The ECC module 112 performs the second ECC operation on the compressed parity codes C_ECC to generate addition parity codes A_ECC, which are stored in the cache memory C1 following the compressed parity codes C_ECC (Step 308). If the size of the combination of the code words CW_1-CW_N, the compressed parity codes C_ECC, the additional parity codes A_ECC and the header is small enough to be filled into the memory unit M1, these codes will be written into the memory unit M1 (Step 310).

In an embodiment, the memory unit M1 includes storage space 9k bytes, which is separated into a data region with 8k bytes for storing data codes and a spare region with 1k bytes for storing parity codes. With a general ECC operation on the data codes, the ECC engine BCH70 may be performed to generate 976-byte parity codes, which are small enough to be stored in the spare region. If the ECC engine BCH90 is performed, 1264-byte parity codes may be generated; these parity codes have a larger size and cannot be written into the spare region.

In order to enhance ECC protection and allow parity codes corresponding to a higher-level ECC engine to be stored in the spare region, the parity codes may be compressed. In this embodiment, the 1264-byte parity codes of BCH90 are compressed with a specific compression ratio, e.g. 68%, and become the compressed parity codes with a size equal to 873 bytes. The ECC engine may further be applied to the compressed parity codes with BCH70 and accordingly generate the additional parity codes with a size equal to 122 bytes. In such a condition, the sum of the sizes of the compressed parity codes and the additional parity codes are 995 bytes, which are small enough to be stored in the spare region. The data codes are protected by BCH90 with an error correction capability 90bits/1 kB, and the parity codes are further protected by BCH70. In comparison with the general ECC operation in which only BCH70 may be applied to the original data codes (BCH90 cannot be applied due to larger parity codes), the embodiment of the present invention enjoys the benefits of a higher ECC capability for the original data codes, and further obtains another ECC protection for the parity codes. Such a two-stage protection substantially enhances the reliability of the data codes. The life of the memory unit M1 can therefore be improved.

Please note that the processor 116 may determine whether the memory unit M1 is large enough for storing the code words CW_1-CW_N, the compressed parity codes C_ECC and the additional parity codes A_ECC according to a compression ratio derived from the parity codes ECC_1-ECC_N and the compressed parity codes C_ECC. The code words CW_1-CW_N, the compressed parity codes C_ECC, the additional parity codes A_ECC and the header are written into the memory unit M1 only when the sum of the size of the code words CW_1-CW_N, the size of the compressed parity codes C_ECC, the size of the additional parity codes A_ECC and the size of the header is smaller than the storage capacity of the memory unit M1. Since the size of the header is quite small with little variations, the sizes of the code words CW_1-CW_N, the compressed parity codes C_ECC and the additional parity codes A_ECC should be controlled to be small enough, which may be achieved by a higher compression ratio. Otherwise, the error correction capabilities of the ECC operations performed on the data codes and the parity codes will be limited. On the other hand, if the sum of the size of the code words CW_1-CW_N, the size of the compressed parity codes C_ECC, the size of the additional parity codes A_ECC and the size of the header is larger than the storage capacity of the memory unit, these codes may not be written into the memory unit. In such a condition, the ECC module 112 will take another ECC policy to re-encode the data codes with a lower level ECC operation (e.g. BCH 70) rather than the higher level ECC operation (e.g. BCH 90) and put the parity codes generated by the lower level ECC operation into the memory unit instead of taking the two-stage ECC protection policy.

In an embodiment, the allocation of the data codes and corresponding parity codes may be arranged in other ways. For example, please refer to FIG. 3B, which is a flow chart of data codes and parity codes to be written into a memory unit M1′ of the non-volatile memory 100 according to an embodiment of the present invention. As shown in FIG. 3B, the data codes and the parity codes to be written into the memory unit M1′ are first stored in a cache memory C1′. The data codes may be divided into code words CW_1′-CW_N′ (Step 312). After the first ECC operation, parity codes ECC_1′-ECC_N′ corresponding to the code words CW_1′-CW_N′ are generated and stored in the cache memory C1′. Different from the arrangement illustrated in FIG. 3A where all of the parity codes ECC_1-ECC_N are placed together following all of the code words CW_1-CW_N, in the cache memory C1′ each set of the parity codes ECC_1′-ECC_N′ is placed next to each of the corresponding code words CW_1′-CW_N′ (Step 314). A header is placed following the N^{th} code word CW_N′ and the N^{th} set of parity codes. The compression module 114 then compresses each set of the parity codes ECC_1′-ECC_N′ to generate a corresponding set of compressed parity codes C_ECC_1-C_ECC_N, respectively, which replaces each set of the parity codes ECC_1′-ECC_N′ to be stored in the cache memory C1′ (Step 316). The ECC module 112 then performs the second ECC operation on each set of the compressed parity codes C_ECC_1-C_ECC_N to generate a corresponding set of addition parity codes A_ECC_1-A_ECC_N. Each set of the addition parity codes A_ECC_1-A_ECC_N is stored in the cache memory C1′ next to the corresponding set of compressed parity codes C_ECC_1-C_ECC_N (Step 318). If the size of the combination of the code words CW_1′-CW_N′, the compressed parity codes C_ECC_1-C_ECC_N, the additional parity codes A_ECC_1-A_ECC_N and the header is small enough to be filled into the memory unit M1′, these codes will be written into the memory unit M1′ (Step 320).

As illustrated above, the arrangement of the code words, the compressed parity codes and the additional parity codes may be placed in the memory unit in any ways; this is not limited herein. Furthermore, the data codes to be stored in the non-volatile memory 100 may not be divided into different code words before undergoing the ECC operations and the compression operations. In other words, the memory unit (e.g. a partial program page) may only include one code word, and thus only one set of compressed parity codes and one set of additional parity codes are generated.

Please note that in Step 204 of the error correction process 20, only the first parity codes are compressed but the data codes are not. This is because the user data stored in the non-volatile memory 100 may most likely be compressed data, especially when the user data includes multimedia content such as music files, pictures or video files. These files have always been compressed, and the compression effect may be very poor if they undergo another compression. If the compression is performed on the combination of the compressed data codes and the first parity codes, the compression effect may also be very poor, which significantly reduces the possibility that the compressed parity codes and the additional parity codes are small enough to be written into the memory unit.

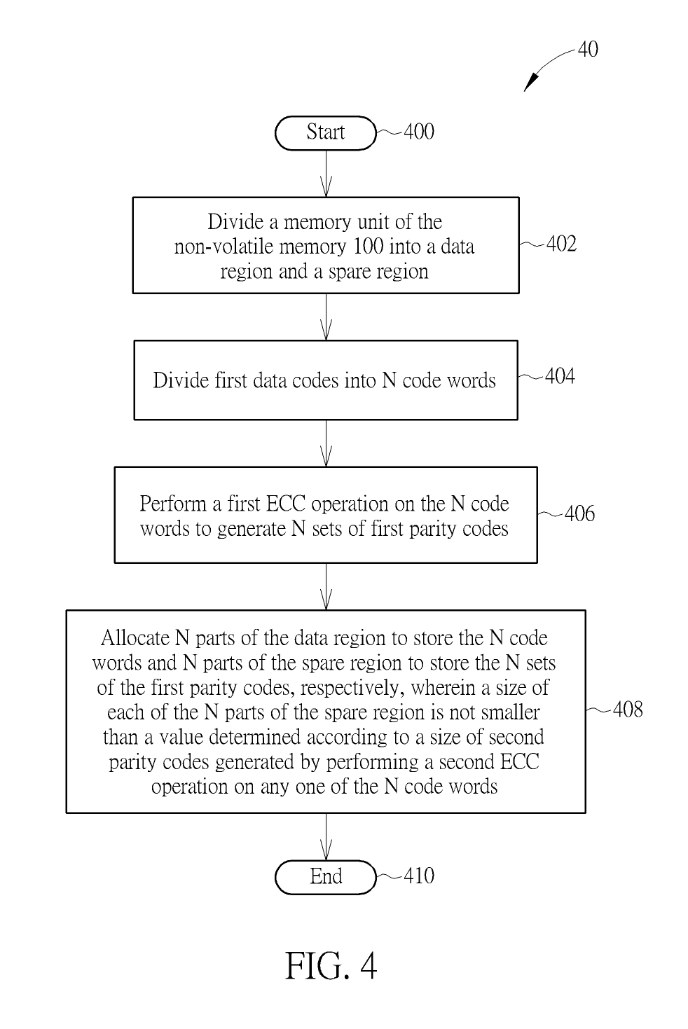

Please refer to FIG. 4, which is an error correction process 40 according to an embodiment of the present invention. As shown in FIG. 4, the error correction process 40, which may be realized by the memory controller 102 of the non-volatile storage device 10, includes the following steps:

Step 400: Start.

Step 402: Divide a memory unit of the non-volatile memory 100 into a data region and a spare region.

Step 404: Divide first data codes into N code words.

Step 406: Perform a first ECC operation on the N code words to generate N sets of first parity codes.

Step 408: Allocate N parts of the data region to store the N code words and N parts of the spare region to store the N sets of the first parity codes, respectively, wherein a size of each of the N parts of the spare region is not smaller than a value determined according to a size of second parity codes generated by performing a second ECC operation on any one of the N code words.

Step 410: End.

According to the error correction process 40, the memory unit of the non-volatile memory 100 is first divided into a data region and a spare region, and data codes stored in the data region are divided into N code words. The ECC module 112 then performs the first ECC operation on the N code words, in order to generate N sets of first parity codes corresponding to the N code words, respectively. Finally, the data region is divided into N parts allocated to store the N code words, respectively, and the spare region is divided into N parts allocated to store the N sets of the first parity codes, respectively.

Please note that the size of each of the N parts of the spare region may not be smaller than a value determined according to a size of second parity codes generated by performing a second ECC operation on any one of the N code words. More specifically, the value may be equal to or greater than the size of the second parity codes generated by performing the second ECC operation on any one of the N code words, where the second ECC operation is expected to be performed in the future. In general, there are fewer error bits in a memory unit when a new non-volatile memory starts to be in use; hence, an ECC policy with lower error correction capability is enough for the memory unit. After undergoing more read/write operations, the bit corruptions of the memory unit will become more severe than in start usage, such that an ECC operation with a higher error correction capability may be required. Therefore, it is desirable to apply a lower level ECC operation (e.g. BCH40) first, and apply a higher level ECC operation (e.g. BCH70) after the number of error bits exceed a threshold value. In such a condition, a storage space accommodating more parity codes required by the higher level ECC operation expected to be applied may be reserved for each of the N code words, even if in the beginning the lower level ECC operation is applied and fewer parity codes are generated. In other words, the size of the second parity codes should be greater than the size of each set of the first parity codes, and the error correction capability of the second ECC operation is higher than that of the first ECC operation.

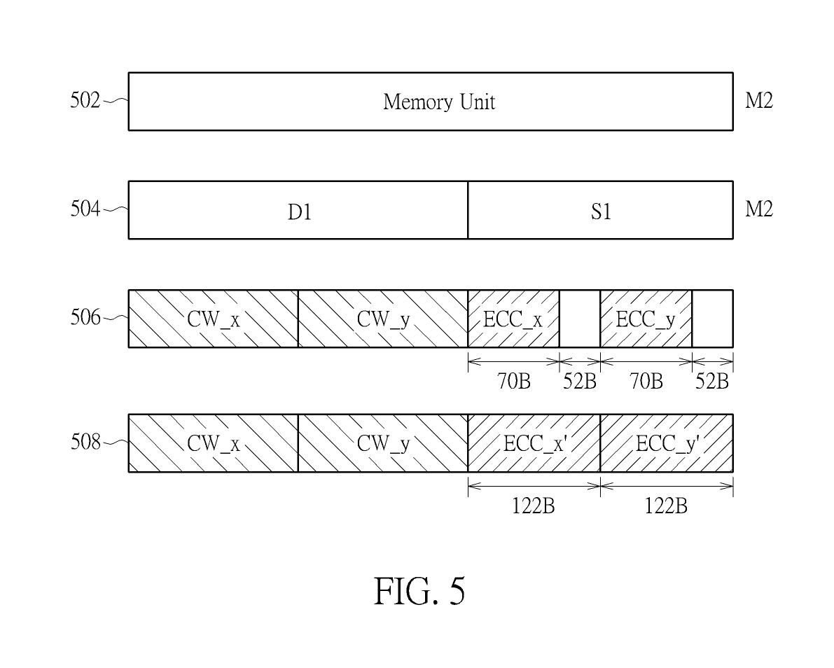

Please refer to FIG. 5, which is a flow chart of storage space in a memory unit M2 reserved for parity codes based on an ECC operation with a higher error correction capability according to an embodiment of the present invention. As shown in FIG. 5, the memory unit (Step 502) is divided into a data region D1 and a spare region S1 (Step 504). The data region D1 stores code words CW_x and CW_y, which are protected by the ECC engine BCH40 with parity codes ECC_x and ECC_y stored in the spare region S1. Each set of the parity codes ECC_x and ECC_y requires 70 bytes. A header is omitted in the memory unit M2 since it has a small size and do not affect the illustration of the present embodiment.

In order to be adaptive to the higher level ECC policy, more storage space is reserved for each code word. For example, the memory unit M2 is expected to be protected by the ECC engine BCH70 after the number of error bits in the memory unit M2 exceeds a threshold value. The ECC engine BCH70 requires 122-byte parity codes ECC_x′ and ECC_y′ for correcting each set of the code words CW_x and CW_y, respectively, so that there is an extra 52-byte storage space reserved following each of the 70-byte parity codes ECC_x and ECC_y (Step 506). After the number of error bits in the memory unit M2 exceeds the threshold value, BCH70 will be applied instead of BCH 40. The parity codes ECC_x′ and ECC_y′ corresponding to BCH70 may replace the parity codes ECC_x and ECC_y and will be stored in each reserved 122-byte storage space, respectively (Step 508).

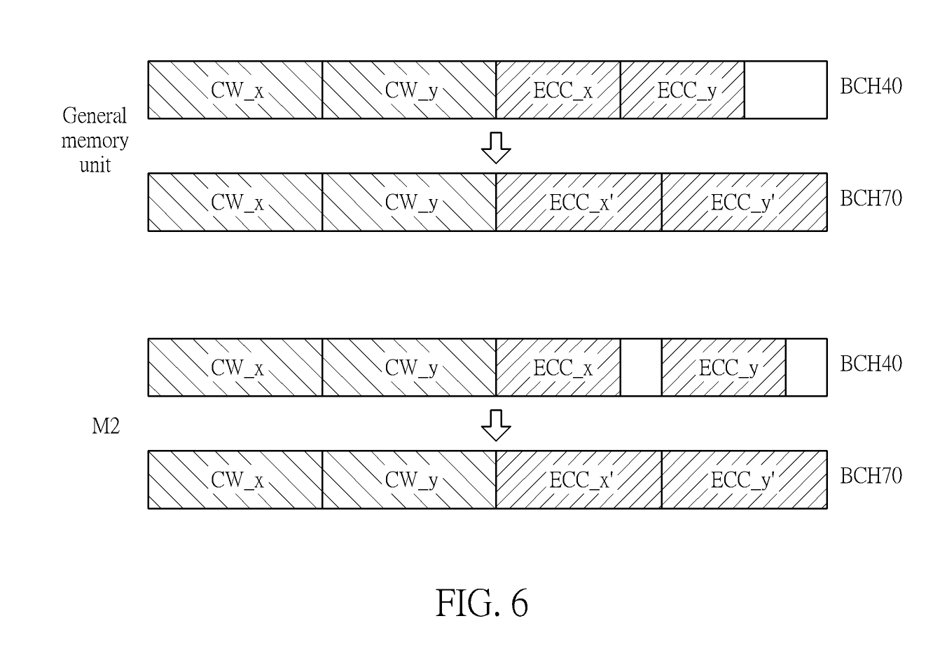

Please refer to FIG. 6, which is a schematic diagram of a comparison between the memory unit M2 in the above embodiment and a general memory unit when a lower level ECC operation (e.g. BCH40) is applied. As shown in FIG. 6, when BCH40 is applied, the general memory unit is filled with the code words CW_x, CW_y and the parity codes ECC_x and ECC_y in order, and a redundant storage space is left behind the parity codes ECC_y for other higher level ECC operations (e.g. BCH70). In such a condition, each time a programming operation is performed on this memory unit, the memory cells in the storage space used for storing the code words CW_x, CW_y and the parity codes ECC_x and ECC_y may undergo wear and tear to some extent, while the memory cells in the redundant storage space undergoes smaller wear. Therefore, this redundant storage space is healthier than other regions in this memory unit. After the number of error bits exceeds a value and BCH70 is applied instead of BCH40, this memory unit is filled by the code words CW_x, CW_y and the parity codes ECC_x′ and ECC_y′ in order. In such a condition, the healthier storage space may most likely be utilized for storing the parity codes ECC_y′. Therefore, the health status of the memory cells storing the parity codes ECC_x′ may be worse than that of the memory cells storing the parity codes ECC_y′, which results in a worse ECC correction capability for the code words CW_x.

In comparison, in the memory unit M2 of the above embodiment, a storage space is reserved following each set of the parity codes ECC_x and ECC_y for a higher level ECC operation (e.g. BCH70) when the lower level ECC operation (e.g. BCH40) is applied. Each of the reserved storage space, which is not used for storing the parity codes ECC_x and ECC_y for BCH40, may be filled with data codes which are most harmless to the memory unit, such as 0xFF. In such a condition, each time a programming operation is performed on the memory unit M2, the memory cells in the storage space used for storing the code words CW_x, CW_y and the parity codes ECC_x and ECC_y may undergo wear and tear to some extent, while the memory cells in the reserved storage spaces undergo smaller wear. Therefore, these reserved storage spaces are healthier than other regions in the memory unit M2. After the number of error bits exceeds a value and BCH70 is applied instead of BCH40, the memory unit M2 is filled with the code words CW_x, CW_y and the parity codes ECC_x′ and ECC_y′ in order. In such a condition, the healthier storage spaces are evenly allocated to the parity codes ECC_x′ and ECC_y′. Therefore, the health status of the memory cells storing the parity codes ECC_x′ may be equal to or close to that of the memory cells storing the parity codes ECC_y′, which results in even ECC correction capability for the code words CW_x and CW_y. This ECC correction capability may be higher than the ECC correction capability for the code words CW_x stored in the general memory unit which are protected by unhealthier parity codes, which improves the life of the memory unit M2.

Please note that the present invention provides a method of handling ECC in a non-volatile memory capable of improving the life of the non-volatile memory by adaptively applying ECC policies. Those skilled in the art may make modifications and alternations accordingly. For example, in the embodiments shown in FIG. 5 and FIG. 6, the memory unit M2 stores two code words. In another embodiment, a memory unit may store any number of code words, and the healthier storage space may be evenly reserved for parity codes for each code word. If the number of code words is larger, the healthier storage space may be spread more evenly, which improves the life of the non-volatile memory much more. In addition, a storage space may also be reserved for the additional parity codes A_ECC in FIG. 3A and A_ECC_1-A_ECC_N in FIG. 3B, in order to accommodate more additional parity codes A_ECC required by performing an ECC operation with a higher error correction capability on the compressed parity codes C_ECC. In addition, the memory units in the embodiments of the present invention may be adaptive to any type of ECC engine and use any type of compression technique; these should not be limited herein.

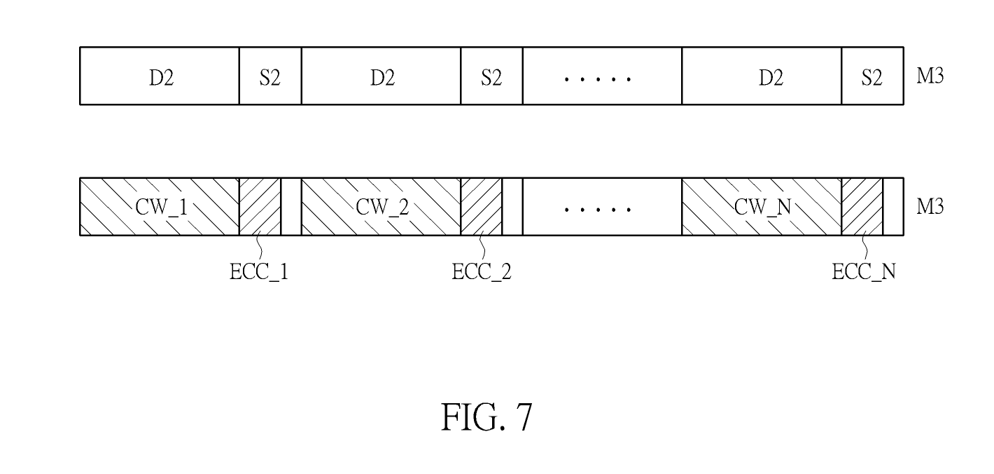

It is notable that in the embodiment of the present invention, the allocation of the data region and the spare region may not be two separate regions. Please refer to FIG. 7, which is a schematic diagram of a placement of a data region D2 and a spare region S2 in a memory unit M3 according to an embodiment of the present invention. As shown in FIG. 7, the data region D2 and the spare region S2 are both divided into N regions and arranged alternately. The N regions of the data region D2 are utilized for storing code words CW_1-CW_N, and the N regions of the spare region S2 are utilized for storing parity codes ECC_1-ECC_N corresponding to the code words CW_1-CW_N, respectively. Each of the N regions of the spare region S2 further includes a reserved storage space for parity codes corresponding to another ECC operation with a higher error correction capability expected to be applied. This arrangement may also be incorporated with the method of ECC handling illustrated in FIG. 5. Detailed operations of the ECC handling of the memory unit M3 are illustrated above, and will not be narrated herein.

To sum up, with the increasing times of program/erase operations performed on the non-volatile memory, bit corruptions will become severe and an ECC policy with a higher error correction capability is therefore required. More parity codes are required for performing higher level error corrections, while there is a finite space for storing these parity codes in the non-volatile memory. Thus, the present invention provides a method of handling ECC in the non-volatile memory. The method is capable of improving the life of the non-volatile memory by adaptively applying ECC policies to efficiently store the parity codes in the limited storage space of the non-volatile memory. In an embodiment, a two-stage ECC protection provides a higher error correction capability for the original data codes and another ECC protection for the compressed parity codes. In another embodiment, storage spaces are reserved for an ECC operation with a higher error correction capability expected to be applied, which allows the healthier storage spaces to be evenly allocated to different sets of parity codes. The life of the non-volatile memory can therefore be improved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of handling an error correcting code (ECC) in a non-volatile memory, comprising:
performing a first ECC operation on data codes to generate first parity codes;
compressing the first parity codes to generate compressed parity codes;
performing a second ECC operation on the compressed parity codes to generate additional parity codes; and
writing the data codes, the compressed parity codes and the additional parity codes into a memory unit of the non-volatile memory.

2. The method of claim 1, further comprising:
writing the data codes and second parity codes into the memory unit when a sum of the size of the data codes, the size of the compressed parity codes and the size of the additional parity codes is not small enough to be written into the memory unit;
wherein the second parity codes are generated via a third ECC operation which has a lower error correction capability than the first ECC operation.

3. The method of claim 1, wherein the memory unit is a memory page or a partial program page of the non-volatile memory.

4. The method of claim 1, wherein the first ECC operation and the second ECC operation are of the same type but with different error correction capabilities, or the first ECC operation and the second ECC operation are of different types.

5. The method of claim 1, further comprising:
determining whether the memory unit is large enough for storing the data codes, the compressed parity codes and the additional parity codes according to a compression ratio of the compressed parity codes.

6. A non-volatile storage device, comprising:
a non-volatile memory; and
a memory controller, coupled to the non-volatile memory, for handling an error correcting code (ECC) in the non-volatile memory, the memory controller comprising:
a memory buffer;
an ECC module, for performing a first ECC operation on data codes stored in the memory buffer to generate first parity codes;
a compression module, for compressing the first parity codes to generate compressed parity codes, wherein the ECC module further performs a second ECC operation on the compressed parity codes to generate additional parity codes; and
a processor, for writing the data codes, the compressed parity codes and the additional parity codes into a memory unit of the non-volatile memory.

7. The non-volatile storage device of claim 6, wherein the processor further writes the data codes and second parity codes into the memory unit when a sum of the size of the data codes, the size of the compressed parity codes and the size of the additional parity codes is not small enough to be written into the memory unit;
wherein the second parity codes are generated via a third ECC operation which has a lower error correction capability than the first ECC operation.

8. The non-volatile storage device of claim 6, wherein the memory unit is a memory page or a partial program page of the non-volatile memory.

9. The non-volatile storage device of claim 6, wherein the first ECC operation and the second ECC operation are of the same type but with different error correction capabilities, or the first ECC operation and the second ECC operation are of different types.

10. The non-volatile storage device of claim 6, wherein the processor further determines whether the memory unit is large enough for storing the data codes, the compressed parity codes and the additional parity codes according to a compression ratio of the compressed parity codes.

11. A method of handling an error correcting code (ECC) in a non-volatile memory, comprising:
dividing a memory unit of the non-volatile memory into a data region and a spare region;
dividing first data codes into N code words;
performing a first ECC operation on the N code words to generate N sets of first parity codes; and
allocating N parts of the data region to store the N code words and N parts of the spare region to store the N sets of the first parity codes, respectively;
wherein a size of each of the N parts of the spare region is not smaller than a value determined according to a size of second parity codes generated by performing a second ECC operation on any one of the N code words.

12. The method of claim 11, wherein the value is greater than a size of each set of the first parity codes, and the method further comprises:
writing second data codes which are most harmless to the memory unit into a spare storage space in each part of the spare region.

13. The method of claim 12, wherein the spare storage space is a storage space which does not store any of the N first parity codes.

14. The method of claim 11, wherein the value is equal to the size of the second parity codes.

15. The method of claim 11, wherein the second ECC operation has a higher error correction capability than the first ECC operation.

16. A non-volatile storage device, comprising:
a non-volatile memory, comprising a memory unit divided into a data region and a spare region; and
a memory controller, coupled to the non-volatile memory, for handling an error correcting code (ECC) in the non-volatile memory by executing the following steps:
dividing first data codes into N code words;
performing a first ECC operation on the N code words to generate N sets of first parity codes; and
allocating N parts of the data region to store the N code words and N parts of the spare region to store the N sets of the first parity codes, respectively;
wherein a size of each of the N parts of the spare region is not smaller than a value determined according to a size of second parity codes generated by performing a second ECC operation on any one of the N code words.

17. The non-volatile storage device of claim 16, wherein the value is greater than a size of each set of the first parity codes, and the memory controller further executes the following step to handle the ECC in the non-volatile memory:
writing second data codes which are most harmless to the memory unit into a spare storage space in each part of the spare region.

18. The non-volatile storage device of claim 17, wherein the spare storage space is a storage space which does not store any of the N first parity codes.

19. The non-volatile storage device of claim 16, wherein the value is equal to the size of the second parity codes.

20. The non-volatile storage device of claim 16, wherein the second ECC operation has a higher error correction capability than the first ECC operation.
